(19) United States
(12) Patent Application Publication
(10) Pub. No.: US 2024/0387231 A1
(43) Pub. Date: Nov. 21, 2024

(54) COLLET FOR PICKUP A SEMICONDUCTOR CHIP

(71) Applicant: Samsung Electronics Co., Ltd., Suwon-si (KR)

(72) Inventors: Jungho PARK, Suwon-si (KR); Hojae KIM, Suwon-si (KR)

(73) Assignee: Samsung Electronics Co., Ltd., Suwon-si (KR)

(21) Appl. No.: 18/521,678

(22) Filed: Nov. 28, 2023

(30) Foreign Application Priority Data
May 16, 2023 (KR) 10-2023-0063132

(51) Int. Cl. H01L 21/683; H01L 21/687

(52) U.S. Cl. CPC H01L 21/6838; H01L 21/68757; H01L 21/68778; H01L 21/68785

(57) ABSTRACT

A collet for pickup a semiconductor chip may include a base and a holder. The base may have a first surface oriented toward the semiconductor chip and a second surface opposite to the first surface. The holder may be arranged at a central portion of the first surface of the base to fix the semiconductor chip using vacuum. An edge portion of the first surface of the base may be exposed. Thus, any structure may not exist in the edge portion of the base corresponding to a peripheral region of the collet so that a peripheral semiconductor chip vertically erected in picking the semiconductor chip from a film may not interfere with the holder. As a result, the vertically erected semiconductor chip may not be stuck in the holder to prevent damages of other semiconductor chip by the vertically erected semiconductor chip.

### CROSS-RELATED APPLICATION

This application claims priority under 35 USC § 119 to Korean Patent Application No. 10-2023-0063132, filed on May 16, 2023 in the Korean Intellectual Property Office (KIPO), the contents of which are herein incorporated by reference in their entirety.

### BACKGROUND

### 1. Field

Example embodiments relate to a collet for pickup a semiconductor chip. More particularly, example embodiments relate to a collet configured to pick up semiconductor chips from a film using vacuum.

### 2. Description of the Related Art

Generally, a mounting process for a semiconductor chip may include a delamination process, a pickup process, etc. The delamination process may delaminate semiconductor chips from a film. A chip ejector may be used in the delamination process. A collet may pick up the semiconductor chip delaminated from the film by the chip ejector using vacuum.

The collet may include a base and a resilient holder. A plurality of vacuum holes may be formed in the base and the holder. The holder may be attached to the whole surface of the base. The holder may have a pickup region configured to pick up the semiconductor chip and a peripheral region configured to surround the pickup region. The pickup region may correspond to a central region of the holder. The peripheral region may correspond to an edge region of the holder.

According to related arts, the holder may have a uniform thickness. That is, a thickness of the holder in the pickup region may be substantially the same as a thickness of the holder in the peripheral region.

However, during the holder may pick up the semiconductor chip from the film, the semiconductor chips around the picked semiconductor chip may be vertically erected. Thus, the vertically erected semiconductor chip may be stuck in the holder in the peripheral region and the semiconductor chip stuck in the holder may damage other semiconductor chips.

### SUMMARY

Example embodiments provide a collet for pickup a semiconductor chip that may be capable of preventing a sticking of a semiconductor chip.

According to example embodiments, there may be provided a collet for pickup a semiconductor chip. The collet may include a base and a holder. The base may have a first surface configured to be oriented toward the semiconductor chip and a second surface opposite to the first surface. The holder may protrude from a central portion of the first surface of the base and be configured to fix the semiconductor chip to a first surface of the holder using vacuum. No structure may protrude from the edge portion of an edge portion of the first surface of the base.

According to example embodiments, there may be provided a collet for pickup a semiconductor chip. The collet may include a base, a resilient holder, and a resilient plate. The base may have a first surface oriented toward the semiconductor chip and a second surface opposite to the first surface. The holder may protrude at a central portion of the first surface of the base and be configured to fix the semiconductor chip to a first surface of the holder using vacuum. The resilient plate may be arranged on an edge portion of the first surface of the base. The base may include a plurality of first vacuum holes configured to receive the vacuum. The holder may include a plurality of second vacuum holes and a vacuum groove. The second vacuum holes may be connected to the first vacuum holes. The second vacuum holes may be exposed through a first surface of the holder. The vacuum groove may be formed at the first surface of the holder to connect the second vacuum holes from each other. The resilient plate may have a thickness of below a distance between the first surface of the holder and the first surface of the base.

According to example embodiments, structures may not exist in the edge portion of the base corresponding to a peripheral region of the collet such that a peripheral semiconductor chip vertically erected in picking the semiconductor chip from a film may not interfere with the holder. According to example embodiments, the thin resilient plate may be arranged in the edge portion of the base such that the vertically erected semiconductor chip may not be stuck in the thin resilient plate. As a result, the vertically erected semiconductor chip may not be stuck in the holder to prevent damages of other semiconductor chip by the vertically erected semiconductor chip.

### BRIEF DESCRIPTION OF THE DRAWINGS

Example embodiments will be more clearly understood from the following detailed description taken in conjunction with the accompanying drawings. FIGS. 1 to 11 represent non-limiting, example embodiments as described herein.

FIG. 1 is a cross-sectional view illustrating a collet for pickup a semiconductor chip in accordance with some example embodiments;

FIG. 2 is an enlarged perspective view illustrating the collet in FIG. 1;

FIG. 3 is a cross-sectional view illustrating the collet in FIG. 2;

FIG. 4 is a cross-sectional view illustrating an operation for pickup a semiconductor chip by the collet in FIG. 1;

FIG. 5 is a cross-sectional view illustrating a collet for pickup a semiconductor chip in accordance with some example embodiments;

FIG. 6 is an enlarged perspective view illustrating the collet in FIG. 5;

FIG. 7 is a cross-sectional view illustrating the collet in FIG. 6;

FIG. 8 is a cross-sectional view illustrating an operation for pickup a semiconductor chip by the collet in FIG. 5;

FIG. 9 is a cross-sectional view illustrating a collet for pickup a semiconductor chip in accordance with some example embodiments;

FIG. 10 is an enlarged perspective view illustrating the collet in FIG. 9; and

FIG. 11 is a cross-sectional view illustrating the collet in FIG. 10.

### DETAILED DESCRIPTION OF THE EMBODIMENTS

Hereinafter, example embodiments will be explained in detail with reference to the accompanying drawings. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Unless otherwise noted, like reference characters denote like elements throughout the attached drawings and written description, and thus repeat descriptions may be omitted.

Additionally, when the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values.

Additionally, although the terms “first,” “second,” “third,” etc., may be used herein to describe various elements, components, regions, layers, and/or sections, these elements, components, regions, layers, and/or sections, should not be limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

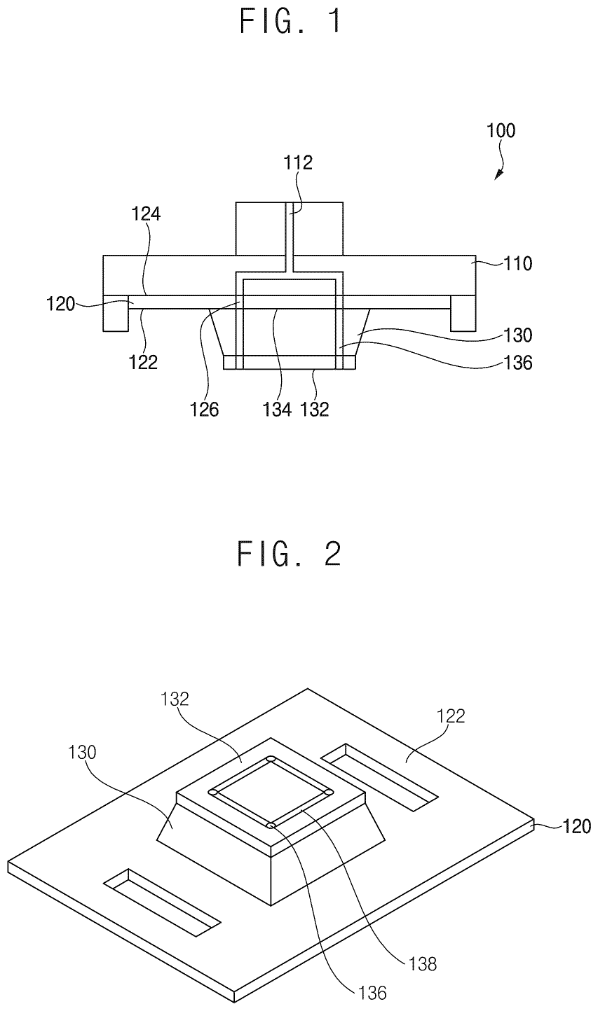

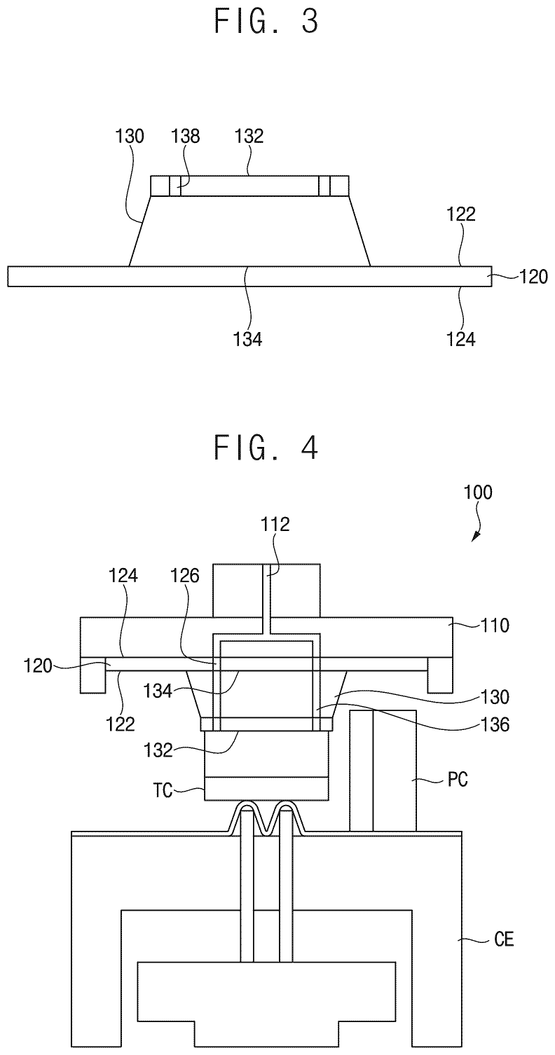

FIG. 1 is a cross-sectional view illustrating a collet for pickup a semiconductor chip in accordance with some example embodiments, FIG. 2 is an enlarged perspective view illustrating the collet in FIG. 1 and FIG. 3 is a cross-sectional view illustrating the collet in FIG. 2.

Referring to FIGS. 1 to 3, a collet 100 for pickup a semiconductor chip in accordance with example embodiments may be arranged over a film to which a plurality of semiconductor chips may be attached. A chip ejector CE may be arranged under the film to delaminate the semiconductor chip from the film. The collet 100 may pick up the semiconductor chip delaminated from the film using vacuum. The collet 100 may include a collet head 110, a base 120 and a holder 130.

The collet head 110 may be configured to be arranged over the film. A vacuum passage 112 may be formed in the collet head 110. The vacuum passage 112 may be vertically formed through the collet head 110. A vacuum pump (not shown) may be connected to the vacuum passage 112 to supply the vacuum to the vacuum passage 112.

The base 120 may be arranged on a first surface of the collet head 110 oriented toward the semiconductor chip. Because the collet head 110 is configured to be positioned over the semiconductor chip, the first surface of the collet head 110 may correspond to a lower surface of the collet head 110. The base 120 may have a first surface 122 and a second surface 124. The first surface 122 of the base 120 may be oriented toward the semiconductor chip. The second surface 124 of the base 120 may be opposite to the first surface 122 of the base 120. The first surface 122 of the base 120 may correspond to a lower surface of the base 120. The second surface 124 of the base 120 may correspond to an upper surface of the base 120. Thus, the second surface 124 of the base 120 may be configured to contact the first surface of the collet head 110.

The base 120 may have a thin thickness. The base 120 may include a metal. For example, the base 120 may include a stainless steel, but is not limited thereto.

The base 120 may include a plurality of first vacuum holes 126. The first vacuum holes 126 may be vertically formed through the base 120. For example, the first vacuum holes 126 may be extended from the second surface 124 to the first surface 122 in the base 120. The first vacuum holes 126 exposed through the second surface 124 of the base 120 may be configured to be connected to the vacuum passage 112 of the collet head 110. Thus, the vacuum introduced into the vacuum passage 112 may be supplied to the first vacuum holes 126.

The holder 130 may be arranged on the first surface 122 of the base 120. The holder 130 may have a first surface 132 and a second surface 134. The first surface 132 of the holder 130 may be oriented toward the semiconductor chip. The second surface 132 of the holder 130 may be opposite to the first surface 132 of the holder 130. The first surface 132 of the holder 130 may correspond to a lower surface of the holder 130. The second surface 134 of the holder 130 may correspond to an upper surface of the holder 130. Thus, the second surface 134 of the holder 130 may be configured to make contact with the central portion of the first surface 122 of the base 120. In at least some embodiments, the holder 130 may be positioned on a central portion of the first surface 122 of the base 120. In contrast, the remainder of the first surface 122 of the base 120 (e.g., an edge portion of the first surface 122) is substantially flat. In other words, a vertical distance between the lowest position of the first surface 122 of the base 120 (and/or any structure thereon and/or protruding therefrom) and the first surface 132 of the holder 130 may be substantially the same as the height of the holder 130, when viewed in cross-section. For example, in at least some example embodiments, other structures may not exist in an edge portion of the first surface 122 of the base 120 such that the edge portion of the first surface 122 of the base 120 may be entirely downwardly exposed. In at least some embodiments, the holder 130 may be adhered to the base 120 through a mechanical fastener (such as a clip, bolt, etc.), a magnetic fastener, an adhesive layer, and/or the like.

The holder 130 may include a plurality of second vacuum holes 136 and a vacuum groove 138. The second vacuum holes 136 may be vertically formed through the holder 130. That is, the second vacuum holes 136 may be extended from the second surface 134 to the first surface 132 in the holder 130. The second vacuum holes 136 exposed through the second surface 134 of the holder 130 may be connected to the first vacuum holes 126 of the base 120. Thus, the vacuum in the first vacuum holes 126 may be introduced into the second vacuum holes 136. In some example embodiments, the second vacuum holes 136 may be positioned adjacent to corners of the first surface 132 of the holder 130, but the examples are not limited thereto.

The vacuum groove 138 may be formed at the first surface 132 of the holder 130. The vacuum groove 138 may be connected between the second vacuum holes 136 exposed through the first surface 132 of the holder 130. Thus, the vacuum introduced into the second vacuum holes 136 may be uniformly distributed in the vacuum groove 138. The vacuum in the vacuum groove 138 may be applied to the delaminated semiconductor chip to pick up the semiconductor chip from the film. In some example embodiments, because the second vacuum holes 136 may be adjacent to the corners of the first surface 132 of the holder 130, the vacuum groove 138 may have a rectangular frame shape connected between the second vacuum holes 136, but the examples are not limited thereto.

Further, the holder 130 may have a vertical trapezoidal cross-sectional shape. Particularly, a length of the first surface 132 of the holder 130 may be shorter than a length of the second surface 134 of the holder 130. That is, the holder 130 may have a reverse pyramidal shape having a flat lower surface. Thus, the first surface 132 of the holder 130 may have an area smaller than an area of the second surface 134 of the holder 130.

In order to prevent damaging the semiconductor chip in the pickup process, the holder 130 may include a resilient material. For example, the holder 130 may include a rubber, but the examples are not limited thereto.

FIG. 4 is a cross-sectional view illustrating an operation for pickup a semiconductor chip by the collet in FIG. 1.

As shown in FIG. 4, the holder 130 may be configured to pick up the semiconductor chip TC delaminated from the film using the vacuum by the chip ejector CE, the peripheral semiconductor chip PC may be vertically erected.

The chip ejector may include a platform and a plurality of pins configured to elevate the semiconductor chip TC, thereby reducing the contact surface area of the semiconductor chip TC and an adhesive film. In at least some embodiments, the pins may elevate the semiconductor chip TC towards the holder 130 and/or the holder 130 may be positioned to contact the semiconductor chip TC and the pins and holder 130 elevated together.

In at least some embodiments, the operation of the chip ejector and the holder 130 may be controlled by, e.g., processing circuitry such as hardware, software, and/or a combination thereof. For example, the processing circuitry more specifically may include (and/or be included in), but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. For example, the relative position of the holder 130 to the semiconductor chip TC, the position of the pins, and/or the activation of the vacuum may be controlled through the activation of actuators using the processing circuitry.

A conventional holder may have a thick portion at the edge portion of the first surface 122 of the base 120 so that the vertically erected peripheral semiconductor chip PC may be stuck in the holder 130. In contrast, according to some example embodiments, structures may not exist in the edge portion of the first surface 122 of the base 120. That is, the holder 130 may be formed by omitting the thick portion of the conventional holder in the edge portion of the first surface 122 of the base 120. Thus, the vertically erected peripheral semiconductor chip PC may not interfere with the holder 130 such that the vertically erected peripheral semiconductor chip PC may not be stuck in the holder 130 and/or compacted by the holder 130.

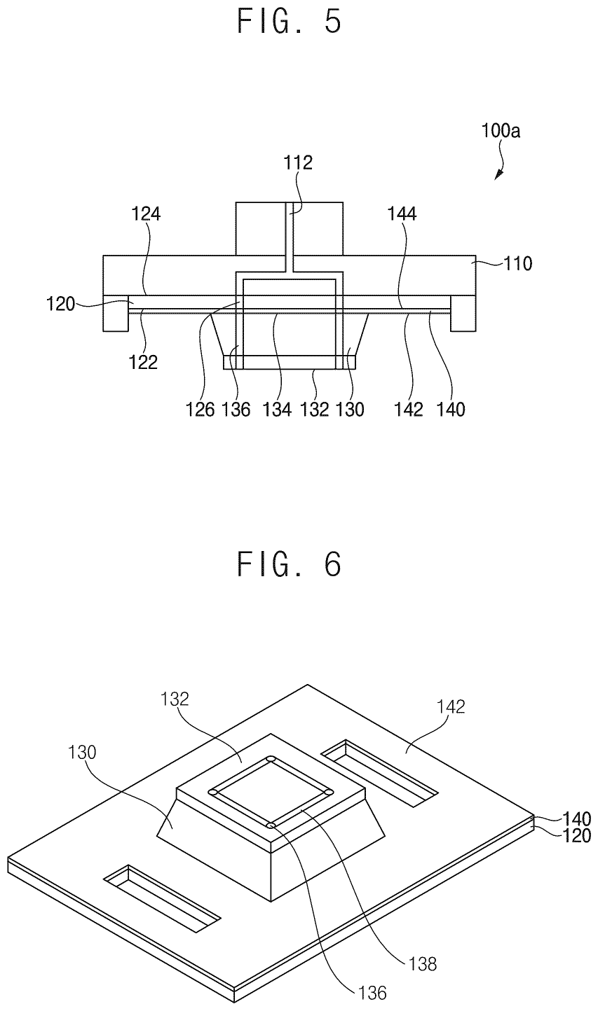

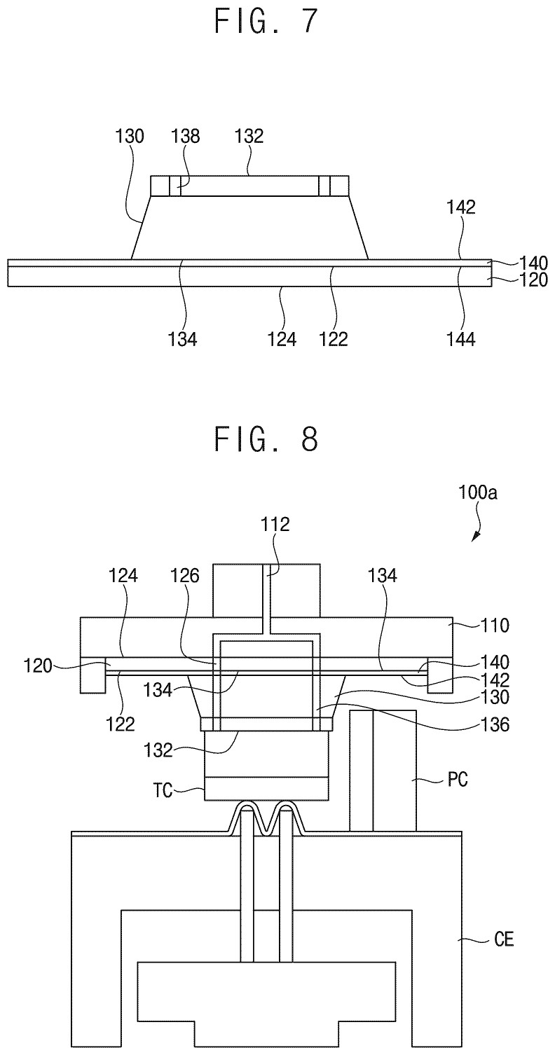

FIG. 5 is a cross-sectional view illustrating a collet for pickup a semiconductor chip in accordance with some example embodiments, FIG. 6 is an enlarged perspective view illustrating the collet in FIG. 5 and FIG. 7 is a cross-sectional view illustrating the collet in FIG. 6.

A collet 100a of some example embodiments may include elements substantially the same as those of the collet 100 in FIG. 1 except for further including a resilient plate 140.

Referring to FIGS. 5 to 7, the collet 100a of example embodiments may further include the resilient plate 140. The resilient plate 140 may be interposed between the base 120 and the holder 130. For example, the resilient plate 140 may be interposed between the first surface 122 of the base 120 and the second surface 134 of the holder 130. Thus, the resilient plate 140 may have a first surface 142 and a second surface 144. The first surface 142 of the resilient plate 140 may make contact with the second surface 134 of the holder 130. The second surface 144 of the resilient plate 140 may make contact with the first surface 122 of the base 120.

Particularly, the resilient plate 140 may make contact with the entire first surface 122 of the base 120. For example, the resilient plate 140 may have an area substantially the same as an area of the first surface 122 of the base 120. Thus, the resilient plate 140 may include a portion positioned at the edge portion of the first surface 122 of the base 120. Therefore, the edge portion of the first surface 122 of the base 120 may be covered by the resilient plate 140. As a result, the edge portion of the first surface 122 of the base 120 may not be downwardly exposed.

In these cases, the peripheral semiconductor chip PC vertically erected in the pickup process may be stuck to the resilient plate 140 if the resilient plate 140 is too thick. In order to prevent the peripheral semiconductor chip PC from being stuck in the resilient plate 140, as shown in FIG. 8, the resilient plate 140 may have a very thin thickness thereby preventing and/or mitigating the sticking of the peripheral semiconductor chip PC. For example, in some example embodiments, the thickness of the resilient plate 140 may be no more than about 0.02% of the vertical distance between the first surface 132 of the holder 130 and the first surface 122 of the base 120. For example, when the distance between the first surface 132 of the holder 130 and the first surface 122 of the base 120 may be about 3,000 μm, the thickness of the resilient plate 140 may be no more than about 60 μm, but the examples are not limited thereto. However, when the thickness of the resilient plate 140 is above about 60 μm, the vertically erected peripheral semiconductor chip PC may interfere with the resilient plate 140 and/or become stuck in the resilient plate 140. Thus, by restricting the thickness of the resilient plate within no more than about 0.02% of the distance between the first surface 132 of the holder 130 and the first surface 122 of the base 120, the vertically erected peripheral semiconductor chip PC may not interfere with the resilient plate 140 and/or may not be stuck in the resilient plate 140. As such, in at least some embodiments, a portion the lower surface 142 of the resilient plate 140 corresponding to the edge portion of the first surface 122 of the base 120 may be substantially flat and/or may be entirely downwardly exposed.

In some example embodiments, the resilient plate 140 may include a material substantially the same as the material of the holder 130, but the examples are not limited thereto. For example, the resilient plate 140 may include (and/or be) a rubber layer. When the material of the resilient plate 140 may be substantially the same as the material of the holder 130, the resilient plate 140 may be formed by partially removing the thick portion of the conventional holder positioned in the edge portion of the first surface 122 of the base 120. Thus, the resilient plate 140 may be integrally formed with the holder 130, but the examples are not limited thereto.

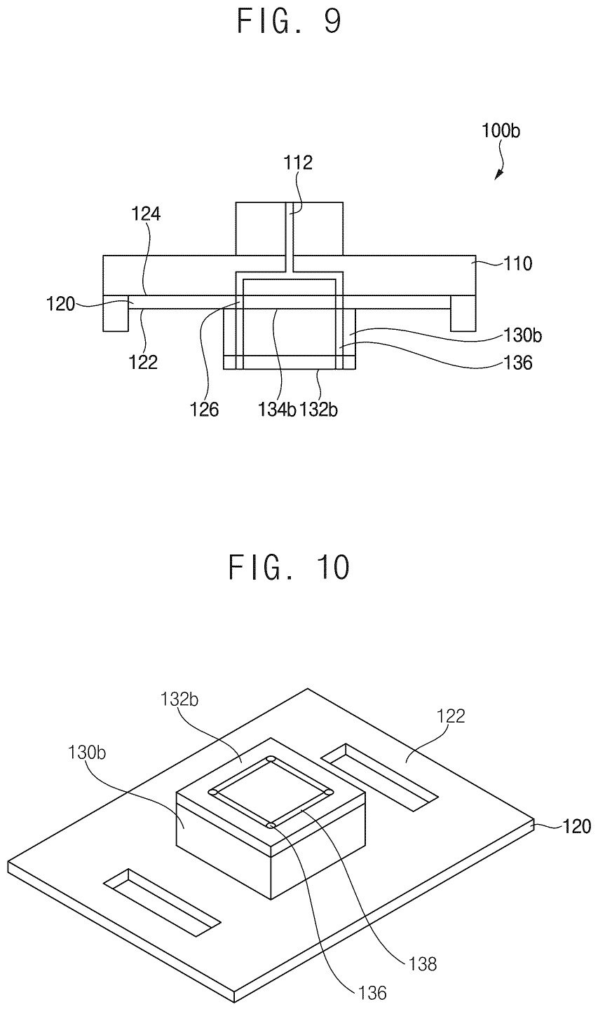

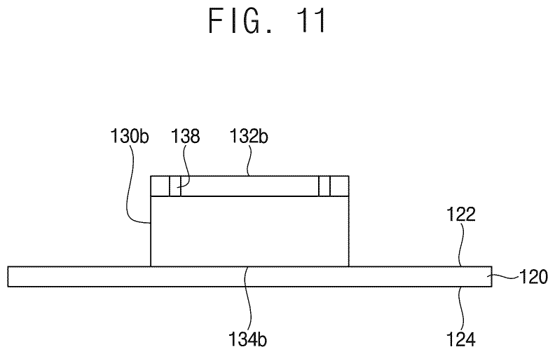

FIG. 9 is a cross-sectional view illustrating a collet for pickup a semiconductor chip in accordance with example embodiments, FIG. 10 is an enlarged perspective view illustrating the collet in FIG. 9 and FIG. 11 is a cross-sectional view illustrating the collet in FIG. 10.

A collet 100b of example embodiments may include elements substantially the same as those of the collet 100 in FIG. 1 except for differences in the shape of the holder 130 and the shape of the holder 130b.

Referring to FIGS. 9 to 11, a holder 130b of example embodiments may have a vertically rectangular cross-sectional shape. That is, the holder 130b may have a cubic shape. Thus, a length of a first surface 132b of the holder 130b may be substantially the same as a length of a second surface 134b of the holder 130b. Therefore, an area of the first surface 132b of the holder 130b may be substantially the same as an area of the second surface 134b of the holder 130b.

Further, in at least some embodiments, the collet 100b of example embodiments may further include the resilient plate 140 in FIG. 5.

As discussed above, the example embodiments, the holder may have the slant or the vertical side surface, but the examples are not limited thereto. For example, the holder may have a side surface including at least one stepped portion.

According to some example embodiments, structures may not exist in the edge portion of the base corresponding to a peripheral region of the collet such that a peripheral semiconductor chip vertically erected in picking the semiconductor chip from a film may not interfere with the holder. Alternatively, the thin resilient plate may be arranged in the edge portion of the base so that the vertically erected semiconductor chip may not be stuck in the thin resilient plate. As a result, the vertically erected semiconductor chip may not be stuck in the holder to prevent and/or mitigate the potential for damaging other semiconductor chip (e.g., by the vertically erected semiconductor chip).

The foregoing is illustrative of example embodiments and is not to be construed as limiting thereof. Although a few example embodiments have been described, those skilled in the art will readily appreciate that many modifications are possible in the example embodiments without droplet departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A collet for pickup of a semiconductor chip, the collet comprising:
a base including a first surface configured to be oriented toward the semiconductor chip and a second surface opposite to the first surface; and
a holder protruding from a central portion of the first surface of the base, the holder configured to fix the semiconductor chip to a first surface of the holder using vacuum,
wherein the first surface of the base has an edge portion and no structure protrudes from the edge portion of the first surface of the base.

2. The collet of claim 1, wherein the base comprises a plurality of first vacuum holes to which the vacuum is provided.

3. The collet of claim 2, wherein the base comprises a metal.

4. The collet of claim 2, wherein the holder comprises a plurality of second vacuum holes connected to the first vacuum holes and exposed through the first surface of the holder.

5. The collet of claim 4, wherein the first surface of the holder further comprises a vacuum groove connecting the second vacuum holes with each other.

6. The collet of claim 1, wherein the holder has a second surface opposite to the first surface of the holder, and the first surface of the holder has a surface area smaller than a surface area of the second surface of the holder.

7. The collet of claim 6, wherein the holder has a trapezoidal vertical cross-sectional shape.

8. The collet of claim 1, wherein the holder has a rectangular vertical cross-sectional shape.

9. The collet of claim 1, wherein the holder comprises a resilient material.

10. The collet of claim 1, further comprising:
a resilient plate on the edge portion of the first surface of the base.

11. The collet of claim 10, wherein the resilient plate has a thickness of about 0.02% or less of a vertical distance between the first surface of the base and the first surface of the holder.

12. The collet of claim 10, wherein the resilient plate comprises a material substantially the same as a material of the holder.

13. The collet of claim 12, wherein the resilient plate is integrally formed with the holder.

14. A collet for pickup a semiconductor chip, the collet comprising:
a base including a first surface oriented toward the semiconductor chip and a second surface opposite to the first surface, the base comprising a plurality of first vacuum holes configured to be provided a vacuum;
a holder protruding from a central portion of the first surface of the base, the holder including a plurality of second vacuum holes connected to the first vacuum holes and exposed through a first surface of the holder and a vacuum groove connecting the second vacuum holes with each other, the holder configured to fix the semiconductor chip to the first surface of the holder using the vacuum; and
a resilient plate on an edge portion of the first surface of the base, the resilient plate having a thickness of about 0.02% or less of a vertical distance between the first surface of the base and the first surface of the holder.

15. The collet of claim 14, wherein the holder has a second surface opposite to the first surface of the holder, and the first surface of the holder has a surface area smaller than a surface area of the second surface of the holder.

16. The collet of claim 15, wherein the holder has a trapezoidal vertical cross-sectional shape.

17. The collet of claim 14, wherein the holder has a rectangular vertical cross-sectional shape.

18. The collet of claim 14, wherein the holder comprises a resilient material.

19. The collet of claim 14, wherein the resilient plate comprises a material substantially the same as a material of the holder.

20. The collet of claim 19, wherein the resilient plate is integrally formed with the holder.
